(19) United States
(12) Patent Application Publication
(10) Pub. No.: US 2020/0116348 A1
(43) Pub. Date: Apr. 16, 2020

(54) COOLING FAN

(71) Applicant: Primax Electronics Ltd., Taipei (TW)

(72) Inventors: Wei-Chiang Huang, Taipei (TW); Ming-Hui Yeh, Taipei (TW); Wei-Ping Chan, Taipei (TW)

(21) Appl. No.: 16/394,750

(22) Filed: Apr. 25, 2019

Related U.S. Application Data
(60) Provisional application No. 62/744,817, filed on Oct. 12, 2018.

(30) Foreign Application Priority Data
Feb. 27, 2019 (TW) 108106818

(51) Int. Cl. F21V 33/00; H05K 7/20

(52) U.S. Cl. CPC F21V 33/0096; F21Y 2115/10; H05K 7/20172

(57) ABSTRACT

A cooling fan includes a fan frame, an impeller mechanism and an illumination module. The fan frame includes an opening and an inner wall. The impeller mechanism is disposed within the opening, and rotatable relative to the fan frame. The illumination module is installed on the fan frame, and emits plural light beams. After the plural light beams are transmitted through the inner wall, the plural light beams are projected to the impeller mechanism. The illumination module and the impeller mechanism of the cooling fan of the present invention are separately arranged. Since the illumination module is not rocked while the impeller mechanism is rotated, the possibility of causing damage of the illumination module will be minimized. Moreover, the stability of controlling the illumination module and the impeller mechanism is also enhanced.

### CROSS-REFERENCE TO RELATED APPLICATION

This application claims priority to U.S. Provisional Patent Application No. 62/744,817 filed Oct. 12, 2018, the contents of which are incorporated herein by reference.

### FIELD OF THE INVENTION

The present invention relates to a heat dissipation device, and more particularly to a cooling fan.

### BACKGROUND OF THE INVENTION

Generally, during operation of an electronic device, a great deal of heat is generated. The heat may influence the performance and stability of the electronic components in the electronic device or shorten the use lives of the electronic components. For maintaining the optimized performance of the electronic device, the electronic device is usually equipped with a heat dissipation module (e.g., a cooling fan) to remove the heat from the operating electronic device. Moreover, for increasing the application and entertainment, an electronic device with a transparent casing has been introduced into the market. Consequently, some specified components within the electronic device can be viewed by the user through the transparent casing. When light-emitting elements are installed on the specified components, the illuminating functions are provided. Moreover, the luminous effects of these components may be determined according to their operating conditions. A cooling fan with an illuminating function is an example of these components.

FIG. 1 schematically illustrates the structure of a conventional cooling fan. As shown in FIG. 1, the conventional cooling fan 1 comprises a fan frame (not shown), an impeller mechanism 11, an electric connection part 12 and plural illumination modules 13. The impeller mechanism 11 comprises a hub 111 and plural blades 112. The hub 111 is fixed on the fan frame. Moreover, the hub 111 is rotatable relative to the fan frame. The plural blades 112 are connected with the hub 111. As the hub 111 is rotated, the plural blades 112 are synchronously rotated with the hub 111 to drive the airflow. The airflow is helpful to dissipate away the heat. The electric connection part 12 is connected with an external power source (not shown) for acquiring electric power to drive the cooling fan 1.

Each illumination module 13 is aligned with one blade 112, and disposed on the corresponding blade 112. The illumination module 13 comprises a circuit board 131, plural light emitting diodes 132, a rotating speed sensor 133 and a control unit 134. The circuit board 131 is fixed on the corresponding blade 112 through a screwing means. The plural light emitting diodes 132 are installed on the circuit board 131. When the plural light emitting diodes 132 are enabled, plural light beams are emitted at a specified lighting frequency. Consequently, the flickering luminous effect is provided. The rotating speed sensor 133 is installed on the circuit board 131. After the rotating speed sensor 133 detects the rotating speed of the blade 112, a rotating speed signal is obtained. The control unit 134 is installed on the circuit board 131 and electrically connected with the plural light emitting diodes 132 and the rotating speed sensor 133. The control unit 134 receives the rotating speed signal from the rotating speed sensor 133. According to the rotating speed signal, the lighting frequency is controlled by the control unit 134. Consequently, the plural light emitting diodes 132 emit the plural light beams at the corresponding lighting frequency.

Moreover, the flickering luminous effect provided by the plural light emitting diodes 132 at the specified lighting frequency may be determined according to the rotating speed of the blade 112. Consequently, the user can feel different visual effects. For example, in response to the human persistence of vision, the cooling fan 1 provides a stationary visual effect. That is, the user feels that the plural blades 112 are in the stationary state. However, in fact, the plural blades 112 are continuously rotated.

Since the illumination module 13 is disposed on the corresponding blade 112, the conventional cooling fan 1 still has some drawbacks. For example, as the blade 112 is continuously rotated, the elements of the illumination module 13 are rocked for a long time period. Consequently, these elements are possibly damaged or even detached from the blade 112.

Therefore, there is a need of providing a cooling fan that is operated stably.

### SUMMARY OF THE INVENTION

An object of the present invention provides a cooling fan that generates a specified visual effect and is operated stably.

In accordance with an aspect of the present invention, a cooling fan is provided. The cooling fan includes a fan frame, an impeller mechanism and an illumination module. The fan frame includes an opening and an inner wall. The impeller mechanism is disposed within the opening, and rotatable relative to the fan frame. The illumination module is installed on the fan frame, and emits plural light beams. After the plural light beams are transmitted through the inner wall, the plural light beams are projected to the impeller mechanism.

In an embodiment, the fan frame further includes a frame body, a receiving structure and a supporting seat. The opening is formed in a middle region of the frame body. Moreover, the opening is enclosed by the inner wall. The receiving structure is arranged around an outer side of the frame body. The illumination module is accommodated within the receiving structure. The supporting seat is connected with the frame body, and located at a central position of the opening. The impeller mechanism is supported by the supporting seat. Moreover, the impeller mechanism is fixed in the opening through the supporting seat.

In an embodiment, the illumination module includes a circuit board, plural light-emitting elements and a control unit. The circuit board is disposed within the receiving structure. The plural light-emitting elements are installed on the circuit board, inserted into the receiving structure, and circumferentially arranged around the opening. The plural light-emitting elements emit the plural light beams. Moreover, the plural light beams are transmitted through the transparent inner wall and projected to the impeller mechanism. The control unit is installed on the circuit board. The control unit controls the plural light-emitting elements to emit the plural light beams at a first lighting frequency or a second lighting frequency.

When the control unit controls the plural light-emitting elements to emit the plural light beams at the first lighting frequency, a driving module of the impeller mechanism drives rotation of the plural blades at a first rotating speed. When the control unit controls the plural light-emitting elements to emit the plural light beams at the second lighting frequency, the driving module of the impeller mechanism drives rotation of the plural blades at a second rotating speed.

As previously described in the conventional cooling fan, the illumination module is installed on the impeller mechanism. When compared with the conventional technologies, the illumination module and the impeller mechanism of the cooling fan of the present invention are separately arranged. Since the illumination module is not rocked while the impeller mechanism is rotated, the possibility of causing damage of the illumination module will be minimized. Moreover, since the illumination module and the impeller mechanism of the cooling fan of the present invention are separately arranged, the stability of controlling the flickering effect of the light-emitting elements is enhanced when compared with the conventional technologies. Moreover, since the illumination module and the impeller mechanism of the cooling fan of the present invention are separately arranged, the stability of controlling the rotating speed of the blades is enhanced when compared with the conventional technologies. Moreover, since the illumination module is not installed on the impeller mechanism according to the present invention, the inner space of the cooling fan can be effectively utilized to install the illumination module. Consequently, the volume of the impeller mechanism can be reduced. Under this circumstance, the cooling fan of the present invention can be installed within a small-sized electronic device (e.g., the heat dissipation device within a computer host).

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 schematically illustrates the structure of a conventional cooling fan;

FIG. 2 is a schematic exploded view illustrating the structure of a cooling fan according to an embodiment of the present invention;

FIG. 3 is a schematic perspective view illustrating the structure of the cooling fan according to the embodiment of the present invention;

FIG. 4 is a schematic cutaway view illustrating the structure of the cooling fan according to the embodiment of the present invention;

FIG. 5 schematically illustrates a first stationary visual effect that is generated by the cooling fan according to the embodiment of the present invention;

FIG. 6 schematically illustrates a second stationary visual effect that is generated by the cooling fan according to the embodiment of the present invention; and

FIG. 7 schematically illustrates a third stationary visual effect that is generated by the cooling fan according to the embodiment of the present invention.

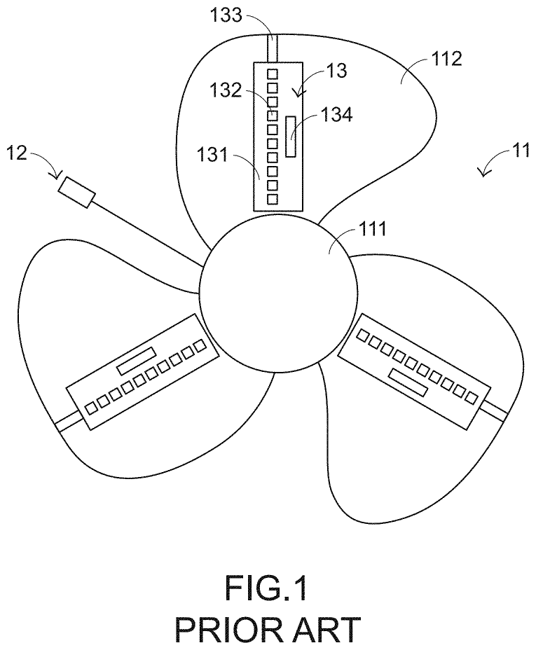

### DETAILED DESCRIPTION OF THE PREFERRED EMBODIMENT

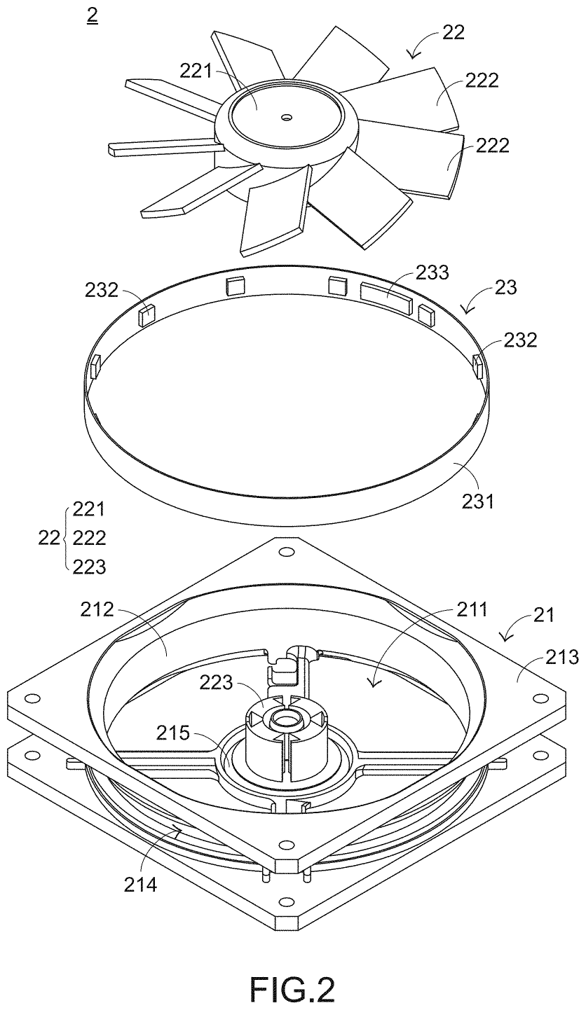

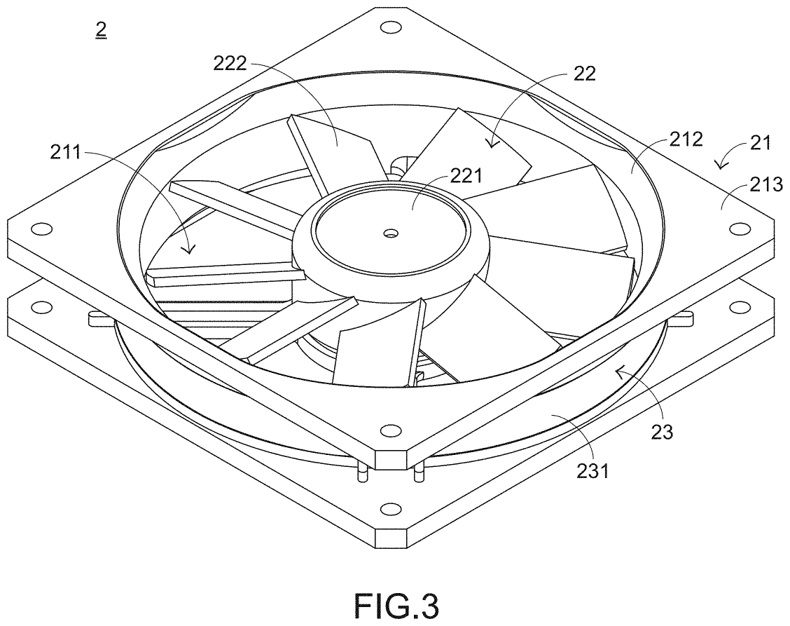

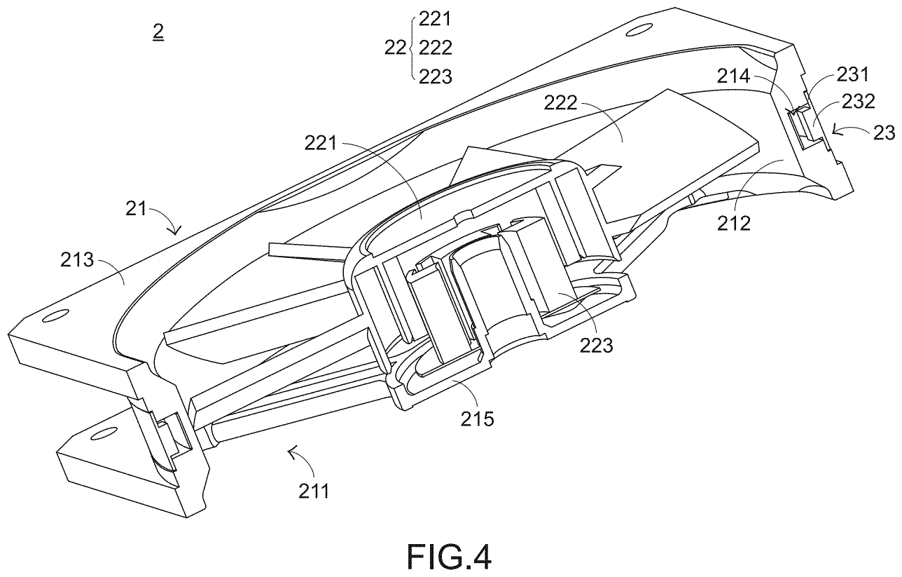

For overcoming the drawbacks of the conventional technologies, the present invention provides a cooling fan. Please refer to FIGS. 2, 3 and 4. FIG. 2 is a schematic exploded view illustrating the structure of a cooling fan according to an embodiment of the present invention. FIG. 3 is a schematic perspective view illustrating the structure of the cooling fan according to the embodiment of the present invention. FIG. 4 is a schematic cutaway view illustrating the structure of the cooling fan according to the embodiment of the present invention. The cooling fan 2 comprises a fan frame 21, an impeller mechanism 22 and an illumination module 23.

The fan frame 21 comprises an opening 211, an inner wall 212, a frame body 213, a receiving structure 214 and a supporting seat 215. The opening 211 is formed in a middle region of the frame body 213. The opening 211 is enclosed by the inner wall 212. In addition, the inner wall 212 is located at an inner side of the frame body 213. The receiving structure 214 is arranged around an outer side of the frame body 213. The illumination module 23 is accommodated within the receiving structure 214. The supporting seat 215 is connected with the frame body 213 and located at a central position of the opening 211. The impeller mechanism 22 is supported by the supporting seat 215. Moreover, the impeller mechanism 22 is fixed in the opening 211 through the supporting seat 215. In an embodiment, the frame body 213 is made of a transparent material. That is, the inner wall 212 at an inner side of the frame body 213 is transparent. Consequently, the frame body 213 is light-transmissible.

The impeller mechanism 22 is disposed within the opening 211 and rotatable relative to the fan frame 21. The impeller mechanism 22 comprises a hub 221, plural blades 222 and a driving module 223. The hub 221 is fixed on the supporting seat 215. That is, the hub 221 is disposed within the opening 211. The hub 221 is rotatable relative to the fan frame 21. The plural blades 222 are connected with the hub 221. As the hub 221 is rotated, the plural blades 222 are synchronously rotated with the hub 221 to drive the airflow. The driving module 223 is disposed on the supporting seat 215 and connected with the hub 221. The driving module 223 is used for driving the rotation of the hub 221 at a specified rotating speed. In an embodiment, the plural blades 222 are integrally formed with the hub 221. It is noted that numerous modifications and alterations may be made while retaining the teachings of the invention. For example, in some other embodiments, the plural blades are connected with the hub in any other appropriate coupling means.

Please refer to FIGS. 2 and 4. The illumination module 23 is installed on the fan frame 21. The illumination module 23 emits plural light beams. After the plural light beams are transmitted through the inner wall 212, the plural light beams are projected on the impeller mechanism 22. In an embodiment, the illumination module 23 comprises a circuit board 231, plural light-emitting elements 232 and a control unit 233. The circuit board 231 is disposed within the receiving structure 214. The plural light-emitting elements 232 are installed on the circuit board 231 and inserted into the receiving structure 214. Moreover, the plural light-emitting elements 232 are circumferentially arranged around the opening 211. The plural light-emitting elements 232 emit plural light beams. After the plural light beams are transmitted through the transparent inner wall 212, the plural light beams are projected to the impeller mechanism 22. The control unit 233 is installed on the circuit board 231 and electrically connected with the plural light-emitting elements 232. The control unit 233 controls the plural light-emitting elements 232 to emit the plural light beams at different lighting frequencies. That is, the flickering luminous effects corresponding to different lighting frequencies are generated. The types of the light-emitting elements 232 are not restricted. For example, the light-emitting element 232 is a light emitting diode (LED) or a micro LED. Moreover, the circuit board 231 is a printed circuit board (PCB) or a flexible printed circuit board (FPC).

In an embodiment, the preset lighting frequencies in the control unit 233 are determined according to the rotating speed of the blade 222. When the plural light-emitting elements 232 emit the plural light beams at the lighting frequencies, the cooling fan 2 provides a stationary visual effect. That is, in response to the flickering luminous effect provided by the plural light-emitting elements 232 and the human persistence of vision, the user feels that the plural blades 222 are in the stationary state while the plural blade 222 are rotated.

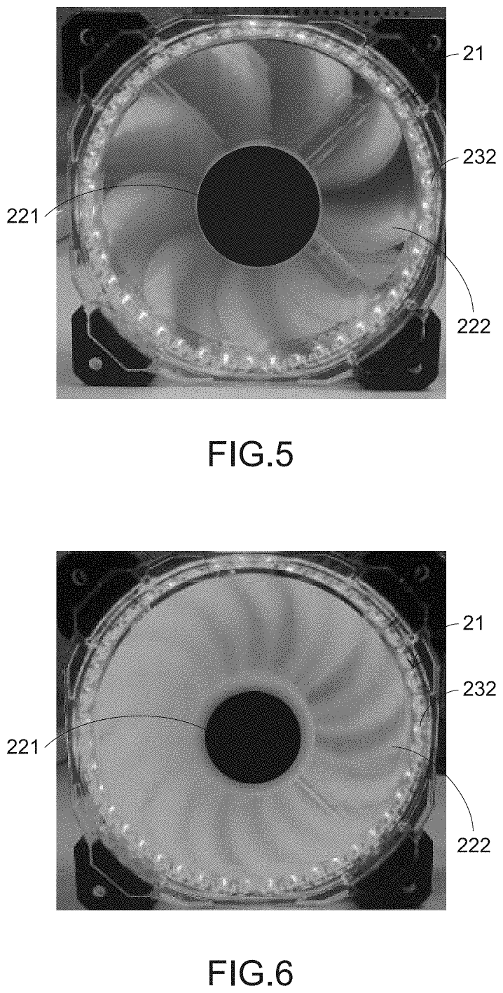

Please refer to FIGS. 3 and 5. FIG. 5 schematically illustrates a first stationary visual effect that is generated by the cooling fan according to the embodiment of the present invention. As shown in FIG. 3, the cooling fan 2 comprises 9 blades 222. When the control unit 233 controls the plural light-emitting elements 232 to emit the plural light beams at a first lighting frequency, the driving module 223 drives the rotation of the plural blades 222 at a first rotating speed. The rotation of the plural blades 222 at the first rotating speed coheres with the first flickering luminous effect of the plural light-emitting elements 232. Consequently, as shown in FIG. 5, the cooling fan 2 provides a first stationary visual effect. When the first flickering luminous effect is provided, the user feels that the plural blades 222 are in the stationary state and 9 blades 222 are obviously visible. However, in fact, the plural blades 222 are continuously rotated.

Please refer to FIGS. 3 and 6. FIG. 6 schematically illustrates a second stationary visual effect that is generated by the cooling fan according to the embodiment of the present invention. As shown in FIG. 3, the cooling fan 2 comprises 9 blades 222. When the control unit 233 controls the plural light-emitting elements 232 to emit the plural light beams at a second lighting frequency, the driving module 223 drives the rotation of the plural blades 222 at a second rotating speed. The rotation of the plural blades 222 at the second rotating speed coheres with the second flickering luminous effect of the plural light-emitting elements 232. Consequently, as shown in FIG. 6, the cooling fan 2 provides a second stationary visual effect. When the second flickering luminous effect is provided, the user feels that the plural blades 222 are in the stationary state and 18 blades 222 are visible. However, in fact, the plural blades 222 are continuously rotated.

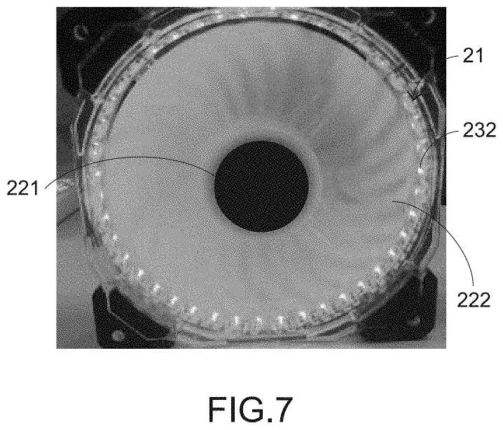

Please refer to FIGS. 3 and 7. FIG. 7 schematically illustrates a third stationary visual effect that is generated by the cooling fan according to the embodiment of the present invention. As shown in FIG. 3, the cooling fan 2 comprises 9 blades 222. When the control unit 233 controls the plural light-emitting elements 232 to emit the plural light beams at a third lighting frequency, the driving module 223 drive the rotation of the plural blades 222 at a third rotating speed. The rotation of the plural blades 222 at the third rotating speed coheres with the third flickering luminous effect of the plural light-emitting elements 232. Consequently, as shown in FIG. 6, the cooling fan 2 provides a third stationary visual effect. When the third flickering luminous effect is provided, the user feels that the plural blades 222 are in the stationary state and 27 blades 222 are visible. However, in fact, the plural blades 222 are continuously rotated.

The following two aspects should be specially described. Firstly, the third rotating speed is faster than the second rotating speed, and the second rotating speed is faster than the first rotating speed. Moreover, the third lighting frequency is higher than the second lighting frequency, and the second lighting frequency is higher than the first lighting frequency. Secondly, the first lighting frequency, the second lighting frequency and the third lighting frequency previously set in the control unit 233 are obtained according to precise calculations and undue experiments. Consequently, the flickering luminous effect of the plural light-emitting elements 232 can cohere with the rotating speed of the plural blades 222.

As previously described in the conventional cooling fan, the illumination module is installed on the impeller mechanism. When compared with the conventional technologies, the illumination module and the impeller mechanism of the cooling fan of the present invention are separately arranged. Since the illumination module is not rocked while the impeller mechanism is rotated, the possibility of causing damage of the illumination module will be minimized. Moreover, since the illumination module and the impeller mechanism of the cooling fan of the present invention are separately arranged, the stability of controlling the flickering effect of the light-emitting elements is enhanced when compared with the conventional technologies. Moreover, since the illumination module and the impeller mechanism of the cooling fan of the present invention are separately arranged, the stability of controlling the rotating speed of the blades is enhanced when compared with the conventional technologies.

Moreover, since the illumination module is not installed on the impeller mechanism according to the present invention, the inner space of the cooling fan can be effectively utilized to install the illumination module. Consequently, the volume of the impeller mechanism can be reduced. Under this circumstance, the cooling fan of the present invention can be installed within a small-sized electronic device (e.g., the heat dissipation device within a computer host).

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. A cooling fan, comprising:
a fan frame comprising an opening and an inner wall;
an impeller mechanism disposed within the opening, and rotatable relative to the fan frame; and
an illumination module installed on the fan frame, and emitting plural light beams, wherein after the plural light beams are transmitted through the inner wall, the plural light beams are projected to the impeller mechanism.

2. The cooling fan according to claim 1, wherein the fan frame further comprises:
a frame body, wherein the opening is formed in a middle region of the frame body, and the opening is enclosed by the inner wall;
a receiving structure arranged around an outer side of the frame body, wherein the illumination module is accommodated within the receiving structure; and
a supporting seat connected with the frame body, and located at a central position of the opening, wherein the impeller mechanism is supported by the supporting seat, and the impeller mechanism is fixed in the opening through the supporting seat.

3. The cooling fan according to claim 2, wherein the impeller mechanism comprises:
a hub fixed on the supporting seat, and rotatable relative to the fan frame;
plural blades connected with the hub, wherein while the hub is rotated, the plural blades are synchronously rotated with the hub; and
a driving module installed on the supporting seat, and connected with the hub, wherein the driving module drives rotation of the hub.

4. The cooling fan according to claim 3, wherein the plural blades are integrally formed with the hub.

5. The cooling fan according to claim 2, wherein the illumination module comprises:
a circuit board disposed within the receiving structure;
plural light-emitting elements installed on the circuit board, inserted into the receiving structure, and circumferentially arranged around the opening, wherein the plural light-emitting elements emit the plural light beams, and the plural light beams are transmitted through the transparent inner wall and projected to the impeller mechanism; and
a control unit installed on the circuit board, wherein the control unit controls the plural light-emitting elements to emit the plural light beams at a first lighting frequency or a second lighting frequency.

6. The cooling fan according to claim 5, wherein when the control unit controls the plural light-emitting elements to emit the plural light beams at the first lighting frequency, a driving module of the impeller mechanism drives rotation of the plural blades at a first rotating speed, wherein when the control unit controls the plural light-emitting elements to emit the plural light beams at the second lighting frequency, the driving module of the impeller mechanism drives rotation of the plural blades at a second rotating speed.

7. The cooling fan according to claim 6, wherein the second rotating speed is faster than the first rotating speed, and the second lighting frequency is higher than the first lighting frequency.

8. The cooling fan according to claim 5, wherein the circuit board is a printed circuit board or a flexible printed circuit board.

9. The cooling fan according to claim 5, wherein the plural light-emitting elements are light emitting diodes or micro light emitting diodes.

10. The cooling fan according to claim 2, wherein the frame body is made of a transparent material.
